(19) United States
(12) Patent Application Publication
(10) Pub. No.: US 2020/0411342 A1
(43) Pub. Date: Dec. 31, 2020

(54) BEAMLINE ARCHITECTURE WITH INTEGRATED PLASMA PROCESSING

(71) Applicant: APPLIED Materials, Inc., Santa Clara, CA (US)

(72) Inventors: Christopher R. Hatem, Seabrook, NH (US); Christopher A. Rowland, Rockport, MA (US); Joseph C. Olson, Beverly, MA (US)

(73) Assignee: APPLIED Materials, Inc., Santa Clara, CA (US)

(21) Appl. No.: 16/455,160

(22) Filed: Jun. 27, 2019

(51) Int. Cl. H01L 21/67; H01J 37/32; H01L 21/677; H01L 21/687; H01L 21/02; H01L 21/265; H01L 21/3065; H01L 21/324

(52) U.S. Cl. CPC H01L 21/67213; H01J 2237/334; H01J 37/32899; H01J 37/32733; H01J 37/32513; H01J 37/32825; H01L 21/67173; H01L 21/67196; H01L 21/67201; H01L 21/67253; H01L 21/67742; H01L 21/68707; H01L 21/02046; H01L 21/0217; H01L 21/02274; H01L 21/26513; H01L 21/3065; H01L 21/324; H01J 2237/186; H01J 2237/24592; H01J 2237/3321; H01J 37/32715

(57) ABSTRACT

A beamline architecture including a wafer handling chamber, a load-lock coupled to the wafer handling chamber for facilitating transfer of workpieces between an atmospheric environment and the wafer handling chamber, a plasma chamber coupled to the wafer handling chamber and containing a plasma source for performing at least one of a plasma pre-clean process, a plasma enhanced chemical vapor deposition process, a plasma annealing process, a pre-heating process, and an etching process on workpieces, a process chamber coupled to the wafer handling chamber and adapted to perform an ion implantation process on workpieces, and a valve disposed between the wafer handling chamber and the plasma chamber for sealing the plasma chamber from the wafer handling chamber and the process chamber, wherein a pressure within the plasma chamber and a pressure within the process chamber can be varied independently of one another.

### FIELD OF THE DISCLOSURE

Embodiments of the present disclosure relate generally to the field of semiconductor device fabrication, and more particularly to a beamline ion implantation architecture with integrated plasma processing.

### BACKGROUND OF THE DISCLOSURE

As electronic components become smaller, more complex, and more powerful, semiconductor devices employed in such components are subject to increasingly restrictive tolerances relating to defects, impurities, and uniformity. When ion implantation is performed on a semiconductor wafer, the wafer's structure, purity, and uniformity can all be negatively affected by the presence of native oxides and organic contaminants on the surface of the wafer prior to ion implantation, as well as by the presence of residual materials, such as residual deposition, etched/sputtered remnants, and polymer chemistries, leftover after ion implantation. Removing surface contaminants from semiconductor wafers before and after ion implantation may therefore be beneficial or necessary for optimizing performance in modern applications. Performing such removal in an efficient, cost-effective manner not adversely affecting wafer throughput and not exposing wafers to atmosphere (where surface contaminants may be introduced to a wafer) has heretofore presented significant challenges.

With respect to these and other considerations the present improvements may be useful.

### SUMMARY

This Summary is provided to introduce a selection of concepts in a simplified form. This Summary is not intended to identify key features or essential features of the claimed subject matter, nor is this Summary intended as an aid in determining the scope of the claimed subject matter.

An exemplary embodiment of a beamline architecture in accordance with an embodiment of the present disclosure may include a wafer handling chamber, a plasma chamber coupled to the wafer handling chamber and containing a plasma source for performing at least one of a pre-ion implantation process and a post-ion implantation process on workpieces, and a process chamber coupled to the wafer handling chamber and adapted to perform an ion implantation process on workpieces.

Another exemplary embodiment of a beamline architecture in accordance with an embodiment of the present disclosure may include a wafer handling chamber, a load-lock coupled to the wafer handling chamber for facilitating transfer of workpieces between an atmospheric environment and the wafer handling chamber, a plasma chamber coupled to the wafer handling chamber and containing a plasma source for performing at least one of a plasma pre-clean process, a plasma enhanced chemical vapor deposition process, a plasma annealing process, a pre-heating process, and an etching process on workpieces, a process chamber coupled to the wafer handling chamber and adapted to perform an ion implantation process on workpieces, and a valve disposed between the wafer handling chamber and the plasma chamber for sealing the plasma chamber from the wafer handling chamber and the process chamber, wherein a pressure within the plasma chamber and a pressure within the process chamber can be varied independently of one another.

An exemplary embodiment of a method for operating a beamline architecture in accordance with an embodiment of the present disclosure may include moving a workpiece from a wafer handling chamber into a plasma chamber, performing at least one of a pre-ion implantation process and a post-ion implantation process on the workpiece, and moving the workpiece from the wafer handling chamber into a process chamber and performing an ion implantation process on the workpiece.

### BRIEF DESCRIPTION OF THE DRAWINGS

By way of example, various embodiments of the disclosed apparatus will now be described, with reference to the accompanying drawings, wherein:

FIG. 1 is a plan view illustrating an exemplary embodiment of a beamline architecture in accordance with the present disclosure;

FIG. 2 is a flow diagram illustrating an exemplary method of operating the beamline architecture shown in FIG. 1;

FIG. 3 is a plan view illustrating another exemplary embodiment of a beamline architecture in accordance with the present disclosure;

FIG. 4 is a plan view illustrating another exemplary embodiment of a beamline architecture in accordance with the present disclosure.

### DETAILED DESCRIPTION

The present embodiments will now be described more fully hereinafter with reference to the accompanying drawings, wherein some embodiments are shown. The subject matter of the present disclosure may be embodied in many different forms and are not to be construed as limited to the embodiments set forth herein. These embodiments are provided so this disclosure will be thorough and complete, and will fully convey the scope of the subject matter to those skilled in the art. In the drawings, like numbers refer to like elements throughout.

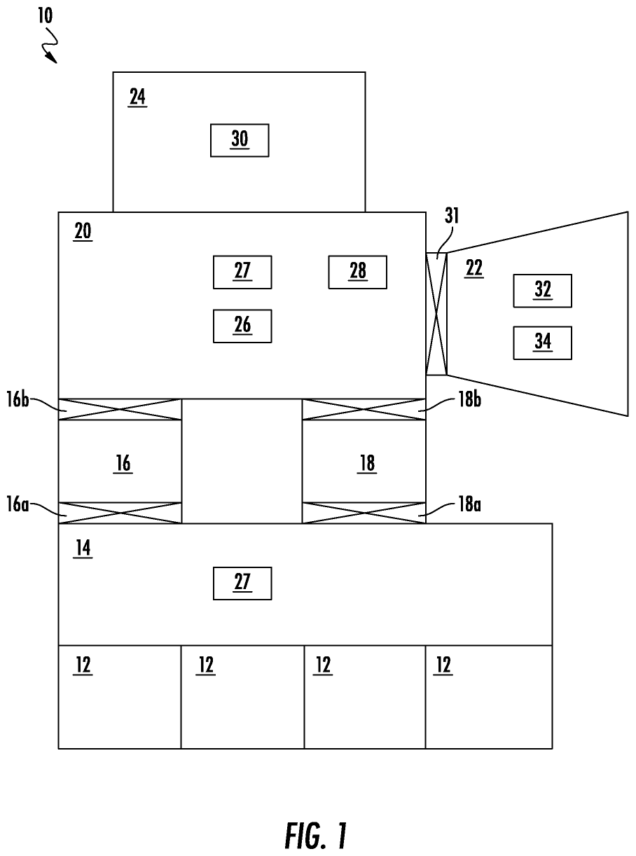

FIG. 1 depicts a beamline architecture 10 (hereinafter “the architecture 10”) according to an exemplary embodiment of the present disclosure. The architecture 10 may include one or more carriers 12, a buffer 14, an entry load-lock 16, an exit load-lock 18, a wafer handling chamber 20, a plasma chamber 22, and a process chamber 24. The entry load-lock 16 and the exit load-lock 18 may include respective valves 16a, 16b and 18a, 18b for maintaining airtight separation between the atmospheric environment of the carriers 12 and the buffer 14 and the vacuum environment of the wafer handling chamber 20, the plasma chamber 22, and the process chamber 24 while also facilitating the transfer of workpieces (e.g., silicon wafers) therebetween as further described below.

The buffer 14 may contain one or more atmospheric robots 25 configured to transfer workpieces from the carriers 12 to the entry load-lock 16 and from the exit load-lock 18 to the carriers 12. The wafer handling chamber 20 may include one or more vacuum robots 26 configured to transfer workpieces between the entry load-lock 16, the plasma chamber 22, the process chamber 24, and the exit load-lock 18 as further described below. The wafer handling chamber 20 may further include an alignment station 27 configured to orient workpieces in a desired manner prior to processing in the process chamber 24. For example, the alignment station 27 may be configured to detect a notch or other indicia on a workpiece to determine and/or adjust the orientation thereof. If workpiece alignment is not required, the alignment station 27 may include a simple pedestal or stand. The alignment station 27 may be also be configured to perform additional functions such as substrate identification.

The wafer handling chamber 20 may further include various metrology components 28. The metrology components 28 may include, and are not limited to, an ellipsometer, a reflectometer, a pyrometer, etc. The metrology components 28 may facilitate the measurement of various aspects and features of workpieces before and after processing in the plasma chamber 22 and/or before and after processing in the process chamber 24. For example, the metrology components 28 may facilitate the detection and measurement of native oxides and other contaminants on the surfaces of workpieces. The metrology components 28 may also facilitate the measurement of thicknesses and compositions of films deposited on the surfaces of workpieces.

The process chamber 24 may be connected to the wafer handling chamber 20 and may include a platen or stage 30 having registration, clamping, and/or cooling mechanisms for receiving to-be-processed workpieces and retaining such workpieces in desired positions and orientations during processing. In various embodiments, the process chamber 24 may be a process chamber of a conventional beamline ion implant apparatus (hereinafter “the ion implanter”) configured to project an ion beam onto a workpiece for ion implantation thereof. The ion implanter (not shown except for the process chamber 24) may include various conventional beamline components including, and not limited to, an ion source, an analyzer magnetic, a corrector magnet, etc. In various embodiments, the ion implanter may generate an ion beam as a spot type ion beam in response to the introduction of one or more feed gases having desired species into the ion source. The present disclosure is not limited in this regard. As will be appreciated by those of ordinary skill in the art, the ion implanter may include various additional beam processing components adapted to shape, focus, accelerate, decelerate, and/or bend the ion beam as the ion beam propagates from the ion source to a workpiece disposed on the platen 30. For example, the ion implanter may include an electrostatic scanner for scanning the ion beam in one or more directions relative to a workpiece.

Like the process chamber 24, the plasma chamber 22 may be connected to the wafer handling chamber 20 and may include a platen or stage 32 for receiving to-be-processed workpieces and retaining such workpieces during processing. A valve 31 may be implemented at the juncture of the plasma chamber 22 and the wafer handling chamber 20 for facilitating airtight separation therebetween. Pressure within the plasma chamber 22 may therefore by regulated independently of the vacuum environment of the wafer handling chamber 20 to accommodate various processes performed in the plasma chamber 22 as further described below.

The plasma chamber 22 may include a plasma source 34 configured to generate an energetic plasma from a gaseous species supplied to the plasma chamber 22 by a gas source (not shown). In various embodiments, the plasma source 34 may be a radio frequency (RF) plasma source (e.g., an inductively-coupled plasma (ICP) source, a capacitively coupled plasma (CCP) source, a helicon source, an electron cyclotron resonance (ECR) source), an indirectly heated cathode (IHC) source, or a glow discharge source. In a particular embodiment, the plasma source 34 may be an RF plasma source and may include an RF generator and an RF matching network. The present disclosure is not limited in this regard.

As will be appreciated by those of ordinary skill in the art, the plasma chamber 22 may be configured to perform various conventional processes on a workpiece disposed on the platen 32. For example, the plasma chamber 22 may be used to perform a plasma cleaning process on a workpiece, wherein plasma-activated atoms and ions of a gaseous species supplied to the plasma chamber 22 may break down organic contaminants on the surface of a workpiece, where after such contaminants may be evacuated from the plasma chamber 22. Plasma cleaning may be performed as part of a so-called “pre-clean” process wherein native oxides and other surface contaminants may be removed from the surface of a workpiece prior to the workpiece being subjected to ion implantation in the process chamber 24. Pre-cleaning may prevent or mitigate “knock-in” of undesired oxygen atoms into workpieces during ion implantation to produce higher quality, better performing workpieces relative to workpieces implanted in the absence of a pre-clean process.

The plasma chamber 22 may also be used to perform plasma enhanced chemical vapor deposition (PECVD) on workpieces, wherein gaseous species may be deposited on the surfaces of workpieces to create thin films of desired materials thereon. For example, a thin film of a desired chemistry may be applied to the surface of a workpiece prior to subjecting the workpiece to an ion implantation process in the process chamber 24, wherein the ion implantation process may activate or interact with the applied chemistry to achieve a desired composition or condition on the surface of the workpiece. In a specific example, a thin doping layer of a desired material may be applied to the surface of a workpiece, where after the applied layer may be knocked into the workpiece with ions in the process chamber 24. In another example, a pre-clean chemistry may be applied via PECVD to remove native oxides. In another example, PECVD may be performed after ion implantation of a workpiece to achieve capping of the workpiece with a film of a desired material (e.g., silicon nitride capping to prevent dopant loss from volatizing during activation anneal).

The plasma chamber 22 may also be used to perform plasma annealing of workpieces after ion implantation. For example, energetic plasma generated by the plasma source 34 may be used to heat a workpiece to a predetermined temperature at a predetermined rate in order to remove defects from the workpiece. For example, an annealing process may include ramping a workpiece to an intermediate temperature of 500-600 degrees Celsius, and then ramping at a rate of 150 degrees Celsius/second to a peak temperature between 850-1050 degrees Celsius. The present disclosure is not limited in this regard.

In other examples, the plasma chamber 22 may be employed for performing various other processes on workpieces before and/or after ion implantation. These include, and are not limited to, heating, cooling, and etching.

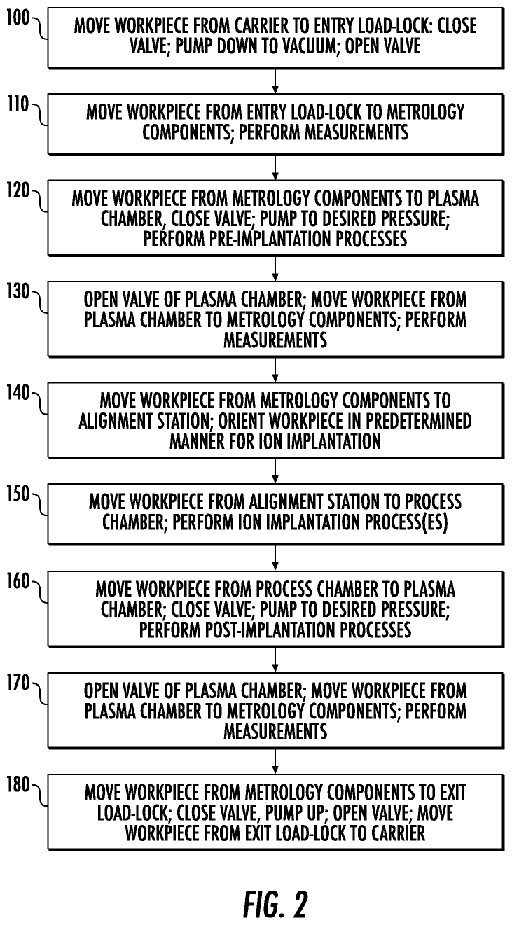

Referring to FIG. 2, a flow diagram illustrating an exemplary method of operating the above-described architecture 10 in accordance with the present disclosure is shown. The method will now be described in detail with reference to the embodiment of present disclosure shown in FIG. 1.

At block 100 of the exemplary method, the atmospheric robot 25 may move a workpiece from one of the carriers 12 to the entry load-lock 16. The valve 16a of the entry load-lock 16 may then be closed and the entry load-lock 16 may be pumped down to vacuum pressure or near vacuum pressure (e.g., 1×10⁻³ Torr). The valve 16b of the entry load-lock 16 may then be opened.

At block 110 of the exemplary method, the vacuum robot 26 may move the workpiece from the entry load-lock 16 to the metrology components 28, where various aspects and features of the workpiece may be measured or detected. For example, the metrology components 28 may be used to detect or measure native oxides and other contaminants on the surface of the workpiece to determine what processes will be performed on the workpiece in the plasma chamber 22 (as described below).

At block 120 of the exemplary method, the vacuum robot 26 may move the workpiece from the metrology components 28 to the platen 32 of the plasma chamber 22. The valve 31 of the plasma chamber 22 may then be closed and a desired pressure may be established within the plasma chamber 22 (e.g., via pumping up or down) for performing one or more pre-ion implantation processes on the workpiece within the plasma chamber 22. In various examples, the workpiece may be subjected to a plasma cleaning process, a PECVD process, a pre-heating process, etc. in the plasma chamber 22 as described above. The present disclosure is not limited in this regard.

At block 130 of the exemplary method, the valve 31 of the plasma chamber 22 may be opened and the vacuum robot 26 may move the workpiece from the platen 32 of the plasma chamber 22 to the metrology components 28 where various aspects and features of the workpiece may be measured or detected. For example, the metrology components 28 may be used to determine whether a plasma cleaning process performed in the plasma chamber 22 was effective to reduce surface contaminants on the workpiece to a level below a predetermined contamination threshold.

At block 140 of the exemplary method, the vacuum robot 26 may move the workpiece from the metrology components 28 to the alignment station 27. The alignment station 27 may be used to orient the workpiece in a desired manner prior to processing in the process chamber 24 (as described below). For example, the alignment station 27 may detect the location of a notch or other indicia on the workpiece and may rotate or otherwise reorient the workpiece to move the notch into a predetermined position.

At block 150 of the exemplary method, the vacuum robot 26 may move the workpiece from the alignment station 27 to the platen 30 in the process chamber 24. The workpiece may then be subjected to one or more ion implantation processes within the process chamber 24 as described above.

At block 160 of the exemplary method, the vacuum robot 26 may move the workpiece from the platen 30 of the process chamber 24 to the platen 32 of the plasma chamber 22. The valve 31 of the plasma chamber 22 may then be closed and a desired pressure may be established within the plasma chamber 22 (e.g., via pumping up or down) for performing one or more post-ion implantation processes on the workpiece within the plasma chamber 22. In various examples, the workpiece may be subjected to a plasma cleaning process, a PECVD capping process, a plasma annealing process, an etching process, etc. in the plasma chamber 22 as described above. The present disclosure is not limited in this regard.

At block 170 of the exemplary method, the valve 31 of the plasma chamber 22 may be opened and the vacuum robot 26 may move the workpiece from the platen 32 of the plasma chamber 22 to the metrology components 28 where various aspects and features of the workpiece may be measured or detected. For example, the metrology components 28 may be used to determine the efficacy of post-ion implantation processes performed in the plasma chamber 22.

At block 180 of the exemplary method, the vacuum robot 26 may move the workpiece from the metrology components 28 to exit load-lock 18. The valve 18b of the exit load-lock 18 may then be closed and the exit load-lock 18 may be pumped up to atmospheric pressure. The valve 18a of the exit load-lock 18 may then be opened and the atmospheric robot 25 may move the workpiece from exit load-lock 18 to one of the carriers 12.

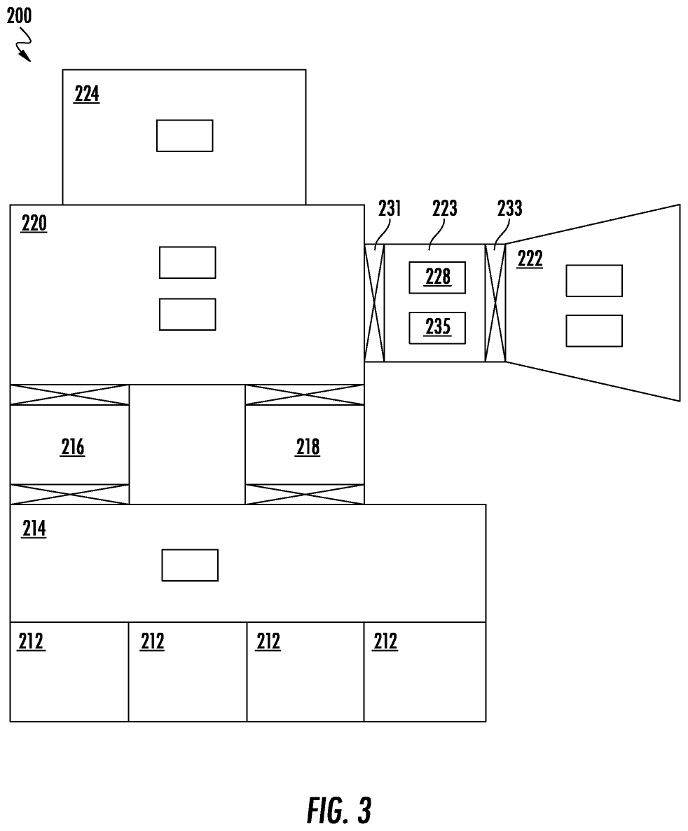

Referring to FIG. 3, a beamline architecture 200 (hereinafter “the architecture 200”) according to another exemplary embodiment of the present disclosure is shown. The architecture 200 may be similar to the architecture 10 described above and may include one or more carriers 212, a buffer 214, an entry load-lock 216, an exit load-lock 218, a wafer handling chamber 220, a plasma chamber 222, and a process chamber 224 similar to corresponding components of the architecture 10 as described above.

Unlike the architecture 10 described above, the architecture 200 may further include a transfer chamber 223 disposed between the wafer handling chamber 220 and the plasma chamber 222. Valves 231, 233 may be implemented at the juncture of the wafer handling chamber 220 and the transfer chamber 223 and at the juncture of the transfer chamber 223 and the plasma chamber 222, respectively, for facilitating airtight separation therebetween. A transfer robot 235 may be disposed within the transfer chamber 223 and may be used to transfer workpieces between the wafer handling chamber 220 and the plasma chamber 222. The transfer chamber 223 may additionally house various metrology components 228 similar to the metrology components 28 described above (e.g., the metrology components 228 may be relocated to the transfer chamber 223 relative to the configuration of the architecture 10). The architecture 200 may be operated in a manner similar to the method described above and illustrated in FIG. 2.

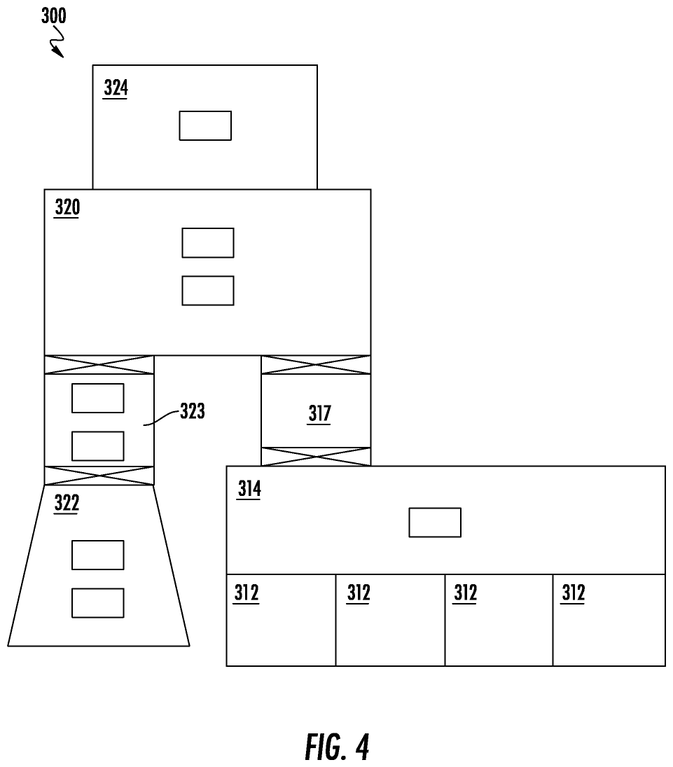

Referring to FIG. 4, a beamline architecture 300 (hereinafter “the architecture 300”) according to another exemplary embodiment of the present disclosure is shown. The architecture 300 may be similar to the architecture 200 described above and may include one or more carriers 312, a buffer 314, a wafer handling chamber 320, a plasma chamber 322, a process chamber 324, and a transfer chamber 323 similar to corresponding components of the architecture 200. Unlike the architecture 200 described above, the architecture 300 may, instead of having separate entry and exit load-locks, include a combination entry/exit load-lock 317 where workpieces may be transferred between the carriers 312 and the wafer handling chamber 320. Additionally, the transfer chamber 323 and the plasma chamber 322 may be located on the same side of the wafer handling chamber 320 as the entry/exit load-lock 317, the buffer 314, and the carriers 312. The architecture 300 may be operated in a manner similar to the method described above and illustrated in FIG. 2.

As will be appreciated by those of ordinary skill in the art, the above-described architectures 10, 200, and 300 and the above-described method provide numerous advantages with regard to beamline processing of semiconductor workpieces. For example, with specific regard to the architecture 10 (and as similarly provided in the architectures 200 and 300), since the plasma chamber 22 and the process chamber 24 are connected directly to the wafer handling chamber 20, processes such as plasma cleaning, PECVD, and plasma annealing may be performed on a workpiece immediately before and/or after subjecting the workpiece to an ion implantation process while avoiding exposing the workpiece to atmosphere (where contaminants may be introduced to the workpiece) when the workpiece is transferred between the plasma chamber 22 and the process chamber 24. Furthermore, since the plasma chamber 22 is separate and apart from the process chamber 24, numerous variables (e.g., pressure, materials, chemistry, etc.) associated with one of the chambers may be varied to effectuate desired processes within such chamber, and the effect of such variables on the other of the chambers need not be considered.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, while the present disclosure has been described herein in the context of a particular implementation in a particular environment for a particular purpose, those of ordinary skill in the art will recognize its usefulness is not limited thereto. Embodiments of the present disclosure may be beneficially implemented in any number of environments for any number of purposes. Accordingly, the claims set forth below shall be construed in view of the full breadth and spirit of the present disclosure as described herein.

1. A beamline architecture comprising:
a wafer handling chamber;
a transfer chamber coupled directly to the wafer handling chamber and being sealable relative to the wafer handling chamber;
a plasma chamber coupled directly to the transfer chamber and containing a plasma source for performing at least one of a pre-ion implantation process and a post-ion implantation process on workpieces, the plasma chamber being sealable relative to the transfer chamber; and
a process chamber coupled directly to the wafer handling chamber and adapted to perform an ion implantation process on workpieces.

2. The beamline architecture of claim 1, further comprising a valve disposed between the wafer handling chamber and the transfer chamber for sealing transfer chamber from the wafer handling chamber and the process chamber.

3. The beamline architecture of claim 1, further comprising a vacuum robot disposed within the wafer handling chamber for moving workpieces between the transfer chamber and the process chamber.

4. The beamline architecture of claim 1, wherein the plasma chamber is adapted to perform at least one of a plasma pre-clean process, a plasma enhanced chemical vapor deposition process, a plasma annealing process, a pre-heating process, and an etching process.

5. The beamline architecture of claim 1, wherein a pressure within the plasma chamber and a pressure within the process chamber can be varied independently of one another.

6. The beamline architecture of claim 1, further comprising metrology components disposed within the wafer handling chamber.

7. (canceled)

8. The beamline architecture of claim 1, further comprising a transfer robot disposed within the transfer chamber for moving workpieces between the wafer handling chamber and the plasma chamber.

9. The beamline architecture of claim 1, further comprising metrology components disposed within the transfer chamber.

10. The beamline architecture of claim 1, further comprising a load-lock coupled to the wafer handling chamber for facilitating transfer of workpieces between an atmospheric environment and the wafer handling chamber.

11. The beamline architecture of claim 1, further comprising an alignment station disposed within the wafer handling chamber.

12. A beamline architecture comprising:
a wafer handling chamber;
a load-lock coupled to the wafer handling chamber for facilitating transfer of workpieces between an atmospheric environment and the wafer handling chamber;
a transfer chamber coupled directly to the wafer handling chamber and being sealable relative to the wafer handling chamber;
a plasma chamber coupled directly to the transfer chamber and containing a plasma source for performing at least one of a plasma pre-clean process, a plasma enhanced chemical vapor deposition process, a plasma annealing process, a pre-heating process, and an etching process on workpieces, the plasma chamber being sealable relative to the transfer chamber;
a process chamber coupled directly to the wafer handling chamber and adapted to perform an ion implantation process on workpieces; and
a valve disposed between the wafer handling chamber and the transfer chamber for sealing the transfer chamber from the wafer handling chamber and the process chamber, wherein a pressure within the transfer chamber and a pressure within the process chamber can be varied independently of one another.

13. A method of operating a beamline architecture including a wafer handling chamber, a transfer chamber coupled directly to the wafer handling chamber and being sealable relative to the wafer handling chamber, a plasma chamber coupled directly to the transfer chamber and being sealable relative to the transfer chamber, and a process chamber coupled directly to the wafer handling chamber, the method comprising:
moving a workpiece from the wafer handling chamber into the transfer chamber;
sealing the transfer chamber relative to the wafer handling chamber;
moving the workpiece from the transfer chamber into the plasma chamber;
performing at least one of a pre-ion implantation process and a post-ion implantation process on the workpiece; and
moving the workpiece from the wafer handling chamber into the process chamber and performing an ion implantation process on the workpiece.

14. The method of claim 13, wherein performing at least one of a pre-ion implantation process and a post-ion implantation process on the workpiece includes performing at least one of a plasma pre-clean process, a plasma enhanced chemical vapor deposition process, and a pre-heating process on the workpiece before performing an ion implantation process on the workpiece.

15. The method of claim 13, wherein performing at least one of a pre-ion implantation process and a post-ion implantation process on the workpiece includes performing at least one of a plasma enhanced chemical vapor deposition process, a plasma annealing process, and an etching process on the workpiece after performing an ion implantation process on the workpiece.

16. The method of claim 13, further comprising sealing the plasma chamber relative to the transfer chamber, the wafer handling chamber and the process chamber.

17. The method of claim 16, further comprising varying a pressure within the plasma chamber relative to a pressure within the wafer handling chamber and the process chamber.

18. (canceled)

19. The method of claim 13, further comprising moving the workpiece to metrology components and measuring at least one of surface contaminants and surface features on the workpiece.

20. The method of claim 13, further comprising moving the workpiece into a load-lock coupled to the wafer handling chamber and transferring the workpiece between an atmospheric environment and the wafer handling chamber.
